(19) United States
(12) Patent Application Publication
(10) Pub. No.: US 2025/0277814 A1
(43) Pub. Date: Sep. 4, 2025

(54) PROBE HEAD WITH ADJUSTABLE PROTRUSION LENGTH OF PROBE

(71) Applicant: TSE CO., LTD., Cheonan-si, Chungcheongnam-do (KR)

(72) Inventors: Seung Bae AN, Cheonan-si (KR); Young Hun JU, Cheonan-si (KR)

(73) Assignee: TSE CO., LTD., Cheonan-si, Chungcheongnam-do (KR)

(21) Appl. No.: 18/859,013

(22) PCT Filed: Nov. 9, 2022
(86) PCT No.: PCT/KR2022/017522

§ 371 Date: Oct. 22, 2024

(30) Foreign Application Priority Data
Apr. 27, 2022 (KR) 10-2022-0051898

(51) Int. Cl. G01R 1/073; G01R 31/26

(52) U.S. Cl. CPC G01R 1/07364; G01R 1/07314; G01R 31/2601

(57) ABSTRACT

Disclosed is a probe head configured such that the height of a spacer constituted by a plurality of blocks is adjusted, whereby the protrusion length of a probe is adjusted. Since the protrusion length of the probe under a lower plate is adjusted, the number of tests is increased, and therefore the lifespan of the probe head is extended. In addition, work time for replacement and reinstallation of the probe head is shortened, whereby delay of a test process is prevented and process cost is reduced.

### TECHNICAL FIELD

The present invention relates to a probe head for testing semiconductor elements, and more particularly to a probe head configured such that the height of a spacer constituted by a plurality of blocks is adjusted, whereby the protrusion length of a probe is adjusted.

### BACKGROUND ART

In general, a semiconductor device manufacturing process includes a patterning process of manufacturing semiconductor elements, an electrical die sorting (EDS) process of electrically testing the semiconductor elements to determine whether the semiconductor elements are defective, and an assembly process of integrating the semiconductor elements on a wafer.

In the EDS process, which is a process of supplying test current to the semiconductor elements and testing electrical signals output from the semiconductor elements to determine whether the semiconductor elements are defective, a probe apparatus configured such that a probe is electrically brought into contact with the semiconductor elements to test performance of the semiconductor elements is widely used.

The probe apparatus includes a tester configured to supply test current and to test and analyze a signal based thereon, a probe card configured to electrically connect an object to be tested (a semiconductor element) and the tester to each other, and a probe configured to be brought into direct contact with the object to be tested and a printed circuit board of the probe card.

The probe is generally configured to have a probe head structure in which a plurality of probes is received and assembled such that the probes stably contact the object to be tested and the probe card while maintaining an appropriate contact pressure and durability of the probes is guaranteed even after a plurality of tests.

In general, the probe head is constituted by a probe and a plate assembly in which the probe is received and assembled. The probe is received in the plate assembly such that a first contact tip and a second contact tip of the probe protrude outwards from a first surface and a second surface of the plate assembly, respectively, so as to electrically contact the printed circuit board and a contact terminal of a semiconductor element to be tested at an appropriate pressure.

The plate assembly may be configured to have various structures capable of receiving and supporting the probe. For a general vertical probe, the plate assembly mainly includes an upper plate having a receiving hole configured to receive the probe formed therein, the upper plate being configured to support an upper side of the probe, a lower plate having a receiving hole configured to receive the probe formed therein, the lower plate being configured to support a lower side of the probe, and a spacer disposed between the upper plate and the lower plate, the spacer being configured to separate the upper plate and the lower plate from each other by a predetermined distance in order to stably support the probe and to provide a space in which the probe is deformed.

During testing, a contact tip of the probe of the probe head is worn due to contact pressure thereof or due to scrubbing between the contact tip of the probe and a contact terminal of the object to be tested.

As a result, the overall lifespan of the probe head is shortened, whereby the number of tests is limited. In addition, work time for replacement and reinstallation of the probe head is added, whereby a test process is delayed and production cost is increased.

### DISCLOSURE

### Technical Problem

It is an object of the present invention to provide a probe head configured such that the height of a spacer constituted by a plurality of blocks is adjusted, whereby the protrusion length of a probe is adjusted.

### Technical Solution

In accordance with the present invention, the above and other objects can be accomplished by the provision of a probe head for testing semiconductor elements, the probe head including an upper plate having a first receiving hole formed therein, a lower plate formed spaced apart from the upper plate, the lower plate having a second receiving hole formed therein, a probe coupled to the upper plate and the lower plate such that an upper part of the probe is received in the first receiving hole, whereby an upper tip protrudes upwards from the upper plate, and a lower part of the probe is received in the second receiving hole, whereby a lower tip protrudes downwards from the lower plate, and a spacer formed between the upper plate and the lower plate to separate the upper plate and the lower plate from each other, thereby providing a space portion capable of receiving a middle part of the probe, wherein the spacer is constituted by a plurality of blocks stacked in an upward-downward direction, and the blocks are configured to be selectively removable to adjust the height of the space portion, whereby the protrusion length of the lower tip of the probe under the lower plate is adjustable.

The spacer may include an upper block, a lower block, and n middle blocks (n being a natural number including 0) provided between the upper block and the lower block.

The upper block, the lower block, and the middle blocks may be identical in size or shape to each other, the upper block, the lower block, and the middle blocks may be different in size or shape from each other, or at least one of the upper block, the lower block, and the middle blocks may be different in size or shape from the other blocks.

In addition, the upper block, the lower block, and the middle blocks may be formed so as to have sequentially changed widths or heights in the upward-downward direction, or the upper block, the lower block, and the middle blocks may have different colors.

In addition, an indicator for position discrimination is provided at a surface of each of the upper block, the lower block, and the middle blocks.

Any one of a concave-convex structure, a screw engagement structure, and an adhesion structure may be formed at coupling surfaces of each of the upper block and the lower block and a corresponding one of the upper plate and the lower plate that face each other such that the coupling surfaces are coupled to each other.

A concave-convex structure may be formed at coupling surfaces of the upper block, the lower block, and the middle blocks that face each other such that the coupling surfaces are coupled to each other by concave-convex coupling, a screw engagement structure may be formed at coupling surfaces of the upper block, the lower block, and the middle blocks that face each other such that the coupling surfaces are coupled to each other by screw engagement, or an adhesion structure may be formed at coupling surfaces of the upper block, the lower block, and the middle blocks that face each other such that the coupling surfaces are coupled to each other by adhesion.

In addition, two or more of a concave-convex structure, a screw engagement structure, and an adhesion structure may be mixedly formed at coupling surfaces of the upper block, the lower block, and the middle blocks that face each other such that the coupling surfaces are coupled to each other.

At least one of the upper block, the lower block, and the middle blocks may be made of an elastic material.

The plurality of blocks may be stacked such that an insertion recess is formed in a lower part of the uppermost block and a block located under the uppermost block is inserted into the insertion recess, and the height of the block inserted into the insertion recess may be equal to or less than the depth of the insertion recess.

The direction in which any one of the plurality of blocks is coupled to the other blocks may be changed to adjust the height of the space portion, and a concave-convex structure or a screw engagement structure is formed at a coupling surface of the block having the changed coupling direction that is to face a coupling surface of a corresponding one of the other blocks.

The upper plate and the upper block or the lower plate and the lower block may be coupled to each other via a variable fastening member.

The spacer may be formed so as to have a quadrangular frame shape such that the space portion is formed in a closed state, or the spacer may be formed so as to have a plurality of bridges located at symmetrical points such that the space portion is formed in an open state.

### Advantageous Effects

As is apparent from the above description, the present invention, which relates to a probe head configured such that the height of a spacer constituted by a plurality of blocks is adjusted, whereby the protrusion length of a probe is adjusted, has the following effects.

First, the present invention has an effect in that the protrusion length of the probe under a lower plate is adjusted, whereby the number of tests is increased, and therefore the lifespan of the probe head is extended.

Second, the present invention has another effect in that work time for replacement and reinstallation of the probe head is shortened, whereby delay of a test process is prevented and process cost is reduced.

Third, the present invention has a further effect in that the protrusion length of the probe is adjustable depending on the degree of wear of the probe, whereby contact between a printed circuit board and a contact terminal of an object to be tested at an appropriate pressure is achieved, and therefore more precise and accurate tests are possible while the printed circuit board and the contact terminal of the object to be tested are protected.

### BRIEF DESCRIPTION OF THE DRAWINGS

The above and other objects, features and other advantages of the present invention will be more clearly understood from the following detailed description taken in conjunction with the accompanying drawings, in which:

FIGS. 1 to 8 are schematic views showing various embodiments of a probe head with an adjustable protrusion length of a probe according to the present invention.

### DETAILED DESCRIPTION OF THE PREFERRED EMBODIMENTS

The present invention relates to a probe head for testing semiconductor elements, and more particularly to a probe head configured such that the height of a spacer constituted by a plurality of blocks is adjusted, whereby the protrusion length of a probe is adjusted.

The protrusion length of the probe under a lower plate is adjusted, whereby the number of tests is increased, and therefore the lifespan of the probe head is extended. In addition, work time for replacement and reinstallation of the probe head is shortened, whereby delay of a test process is prevented and process cost is reduced.

Furthermore, the protrusion length of the probe is adjustable depending on the degree of wear of the probe, whereby contact between a printed circuit board and a contact terminal of an object to be tested at an appropriate pressure is achieved, and therefore more precise and accurate tests are possible while the printed circuit board and the contact terminal of the object to be tested are protected.

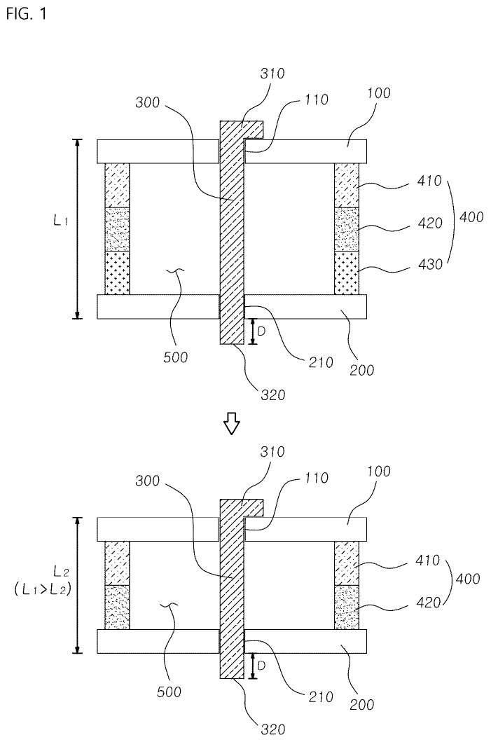

Hereinafter, embodiments of the present invention will be described in detail with reference to the accompanying drawings. FIGS. 1 to 8 are schematic views showing various embodiments of a probe head with an adjustable protrusion length of a probe according to the present invention.

As shown, the probe head with the adjustable protrusion length of the probe 300 according to the present invention includes an upper plate 100 having a first receiving hole 110 formed therein, a lower plate 200 formed spaced apart from the upper plate 100, the lower plate 200 having a second receiving hole 210 formed therein, a probe 300 coupled to the upper plate 100 and the lower plate 200 such that an upper part of the probe is received in the first receiving hole 110, whereby an upper tip 310 protrudes upwards from the upper plate 100, and a lower part of the probe is received in the second receiving hole 210, whereby a lower tip 320 protrudes downwards from the lower plate 200, and a spacer 400 formed between the upper plate 100 and the lower plate 200 to separate the upper plate 100 and the lower plate 200 from each other, thereby providing a space portion 500 capable of receiving a middle part of the probe 300, wherein the spacer 400 is constituted by a plurality of blocks stacked in an upward-downward direction, and the blocks are configured to be selectively removable in order to adjust the height of the space portion 500, whereby the protrusion length of the lower tip 320 of the probe 300 under the lower plate 200 is adjustable.

The probe head according to the present invention mainly includes an upper plate 100, a lower plate 200, a probe 300 coupled to the upper plate 100 and the lower plate 200, and a spacer configured to separate the upper plate 100 and the lower plate 200 from each other and to support the upper plate 100 and the lower plate 200.

In particular, the spacer 400 according to the present invention is constituted by a plurality of blocks stacked in the upward-downward direction, and the blocks are configured to be selectively removable in order to adjust the height of a space portion 500 defined by the upper plate 100, the lower plate 200, and the spacer 400, whereby the protrusion length of the probe 300 is adjustable.

In general, while a semiconductor element is tested, a contact tip of the probe 300 is worn due to contact pressure against a printed circuit board and an object to be tested or due to scrubbing between the contact tip of the probe 300 and a contact terminal of the object to be tested.

As a result, the overall lifespan of the probe head is shortened, whereby the number of tests is limited. In addition, work time for replacement and reinstallation of the probe head is added, whereby a test process is delayed and production cost is increased.

That is, since the protrusion length of the probe 300 is decreased as the number of tests is increased, the plurality of stacked blocks may be selectively removed in order to adjust the protrusion length of the lower tip 320 of the probe 300 under the lower plate 200 such that the probe 300 is brought into contact with the printed circuit board and the contact terminal of the object to be tested at an appropriate pressure, whereby the number of tests is increased in the state in which more precise and accurate tests are possible.

The probe 300 according to the present invention may have any shape or may be made of any material in order to test conventional semiconductor elements. In addition, each of the upper plate 100 and the lower plate 200 may have any shape as long as it is possible to stably receive the probe 300 and to guide and support a space portion in which the probe 300 is slid, received, and moved. Furthermore, each of the upper plate 100 and the lower plate 200 may be provided in single or plural in order to stably and effectively support the probe 300 depending on the probe 300.

Several thousands to several tens of thousands of probes 300 are coupled to the receiving holes of the upper plate 100 and the lower plate 200, and are repeatedly slid upwards and downwards and bent in the receiving holes to perform tests. In the present invention, a description will be given based on the structure in which one probe 300 is coupled to the upper plate 100 and the lower plate 200 for sake of convenience.

A probe head according to an embodiment of the present invention includes an upper plate 100 having a first receiving hole 110 formed therein, a lower plate 200 formed spaced apart from the upper plate 100, the lower plate 200 having a second receiving hole 210 formed therein, and a probe 300 coupled to the upper plate 100 and the lower plate 200 such that an upper part of the probe is received in the first receiving hole 110, whereby an upper tip 310 protrudes upwards from the upper plate 100, and a lower part of the probe is received in the second receiving hole 210, whereby a lower tip 320 protrudes downwards from the lower plate 200.

Here, the probe 300 may be made of an elastic metal or a metal composite material that has elasticity, and a needle type pin, which is usually called a cobra pin, may be provided as the probe 300. The upper tip 310 protrudes upwards from the upper plate 100, and the lower part of the probe is received in the second receiving hole 210, whereby the probe 300 is brought into stable contact with the printed circuit board and the contact terminal of the object to be tested while being bent in the space portion 500.

The spacer 400 according to the present invention is formed between the upper plate 100 and the lower plate 200 to separate the upper plate 100 and the lower plate 200 from each other, thereby providing a space portion 500 capable of receiving a middle part of the probe 300.

The spacer 400 is formed between the upper plate 100 and the lower plate 200 so as to separate the upper plate 100 and the lower plate 200 from each other and to support the upper plate 100 and the lower plate 200, and provides a space portion 500 in which the probe 300 may be moved or bent.

The spacer 400 is formed so as to have a quadrangular frame shape such that the space portion 500 is formed in a closed state or is formed so as to have a plurality of bridges located at symmetrical points such that the space portion 500 is formed in an open state.

That is, the spacer 400 is formed along the circumference of each of the upper plate 100 and the lower plate 200 at corners or adjacent to the corners thereof in response to the shape of each of the upper plate 100 and the lower plate 200 so as to have a quadrangular frame shape, whereby the space portion 500 is formed so as to be surrounded by the upper plate 100, the lower plate 200, and the quadrangular-frame-shaped spacer.

Alternatively, the spacer 400 is formed so as to have bridges located at symmetrical points, e.g. opposite corners or vertices of the upper plate 100 and the lower plate 200, or adjacent thereto such that the space portion 500 is formed in an open state.

The spacer 400 according to the present invention is constituted by a plurality of blocks stacked in the upward-downward direction, and the blocks are configured to be selectively removable in order to adjust the height of the space portion 500, whereby the protrusion length of the lower tip 320 of the probe 300 under the lower plate 200 is adjustable.

FIGS. 1 to 8 show various embodiments of the present invention, wherein the upper plate 100, the lower plate 200, the spacer 400 formed between the upper plate 100 and the lower plate 200, and the probe 300 coupled to the upper plate 100 and the lower plate 200 are schematically shown. The spacer 400 is constituted by a plurality of blocks stacked in the upward-downward direction to determine heights L1, L2, and L3 of the space portion 500.

When the probe 300 is worn and thus the length of the probe 300 is decreased during testing, one or more of the plurality of blocks constituting the spacer 400 is removed by a length corresponding thereto or by a length necessary to maintain appropriate contact pressure against the printed circuit board and the contact terminal of the object to be tested as needed, whereby the height of the space portion 500 is adjusted, and therefore the protrusion length D of the lower tip 320 of the probe 300 under the lower plate 200 is adjusted.

The spacer 400 according to the present invention includes an upper block 410, a lower block 430, and n middle blocks 420 (n being a natural number including 0) provided between the upper block 410 and the lower block 430. That is, the spacer 400 according to the present invention is constituted by at least two blocks. When the length of the probe 300 is decreased, at least one of the blocks is removed, whereby the height of the space portion 500 is adjusted, and therefore the protrusion length of the lower tip 320 of the probe 300 under the lower plate 200 is adjusted.

The upper block 410, the lower block 430, and the middle blocks 420 may be identical in size or shape to each other, may be different in size or shape from each other, or at least one of the upper block 410, the lower block 430, and the middle blocks 420 may be different in size or shape from the other blocks. The reason for this is that, when the blocks constituting the spacer 400 are identical in size or shape to each other or at least one block is formed so as to be different in size or shape from the other blocks, the degree of freedom in adjusting the height of the space portion 500 is further improved. That is, the protrusion length of the probe 300 is most appropriately adjusted depending on the degree of wear of the probe 300.

In addition, the upper block 410, the lower block 430, and the middle blocks 420 may be formed so as to have sequentially changed widths or heights in the upward-downward direction or to have different colors. Alternatively, an indicator for discrimination may be further formed on the surface of each block.

As a result, a block to be removed is easily recognized, whereby the height of the space portion 500 is conveniently adjusted. That is, a block having a specific width, height, or color is easily distinguished from the other blocks, and whereby removal of a wrong block is minimized and removal of a correct block is rapidly and easily achieved when adjusting the height of the space portion 500.

In addition, an indicator for discrimination in height or position, e.g. an Arabic numeral, a Korean consonant, or a letter, may be marked on the surface of each block such that the indicator can be recognized from outside, whereby a block having a specific height is accurately and rapidly removed.

Any one of a concave-convex structure 600, a screw engagement structure 700, and an adhesion structure 800 is formed at coupling surfaces of each of the upper block 410 and the lower block 430 and a corresponding one of the upper plate 100 and the lower plate 200 that face each other such that the coupling surfaces are coupled to each other.

That is, each of the upper block 410 and the lower block 430 and a corresponding one of the upper plate 100 and the lower plate 200 are stably coupled to each other via a coupling means, such as the concave-convex structure 600, the screw engagement structure 700, or the adhesion structure 800, and are easily separated from each other when each block is removed.

In the concave-convex structure 600, a concave portion and a convex portion are formed at the coupling surfaces that face each other so as to correspond to each other such that the coupling surfaces are coupled to each other by concave-convex coupling. In the screw engagement structure 700, screw holes for screw fastening are formed in the coupling surfaces that face each other such that the coupling surfaces are coupled to each other by screw engagement. In the adhesion structure 800, adhesive members are formed on the coupling surfaces that face each other such that the coupling surfaces are coupled to each other by adhesion.

In addition, the concave-convex structure 600 may be formed at coupling surfaces of the upper block 410, the lower block 430, and the middle blocks 420 that face each other such that the coupling surfaces are coupled to each other by concave-convex coupling, the screw engagement structure 700 may be formed at the coupling surfaces of the upper block 410, the lower block 430, and the middle blocks 420 that face each other such that the coupling surfaces are coupled to each other by screw engagement, or the adhesion structure 800 may be formed at the coupling surfaces of the upper block 410, the lower block 430, and the middle blocks 420 that face each other such that the coupling surfaces are coupled to each other by adhesion.

Alternatively, two or more of the concave-convex structure 600, the screw engagement structure 700, and the adhesion structure 800 are mixedly formed at the coupling surfaces of the upper block 410, the lower block 430, and the middle blocks 420 that face each other such that the coupling surfaces are coupled to each other by two or more of concave-convex coupling, screw engagement, and adhesion.

That is, not only coupling between each plate and a corresponding block but also coupling between the blocks is stably performed by the coupling means. In addition, block removal is rapidly performed by separation between the concave portion and the convex portion, screw disengagement, or separation between the adhesive members, and then recoupling between the blocks is easily performed by the coupling means.

Meanwhile, at least one of the upper block 410, the lower block 430, and the middle blocks 420 may be made of an elastic material that exhibits higher elasticity than the other blocks. As a result, the height of the space portion 500 is elastically changed, whereby the probe 300 is brought into elastic contact with the printed circuit board and the contact terminal of the object to be tested.

In another embodiment of the present invention, the spacer 400 is constituted by a plurality of blocks stacked in the upward-downward direction, and the blocks are stacked such that an insertion recess 440 is formed in a lower part of an uppermost block and a block located under the uppermost block is inserted into the insertion recess 440, wherein the height of the block inserted into the insertion recess 440 is equal to or less than the depth of the insertion recess 440.

When an upper block 410 is removed, the height of the space portion 500 is set by a middle block 420 (or a lower block 430) that was inserted into the insertion recess 440 of the upper block 410, and the protrusion length of the lower tip 320 of the probe 300 is adjusted by the difference in height between the upper block 410 and the middle block 420 (or the lower block 430).

In another embodiment of the present invention, the direction in which any one of the plurality of blocks is coupled to the other blocks may be changed to adjust the height of the space portion 500.

That is, the direction in which the blocks constituting the spacer 400 are coupled to each other is changed to change the height of the spacer 400. The direction in which the blocks are stacked horizontally or vertically or the direction in which the blocks are coupled to each other is changed based on the difference in horizontal or vertical height between the blocks, and neighboring blocks are recoupled to each other, whereby the height of the spacer 400 is changed.

When the direction in which the blocks are coupled to each other is changed, as described above, the concave-convex structure 600 or the screw engagement structure 700 is formed at coupling surfaces of the neighboring blocks that are to face each other. Alternatively, the concave-convex structure 600 or the screw engagement structure 700 is formed at coupling surfaces of one of the blocks stacked in the state in which the coupling direction thereof is changed and the upper plate 100 or the lower plate 200 that are to face each other, whereby coupling therebetween is stably performed.

In another embodiment of the present invention, the upper plate 100 and the upper block or the lower plate 200 and the lower block may be coupled to each other via a variable fastening member 900.

The variable fastening member 900 is constituted by a screw thread having a predetermined length and a screw head. The variable fastening member 900 is configured such that, when the upper plate 100 and the upper block are coupled to each other by screw engagement and when the lower plate 200 and the lower block are coupled to each other by screw engagement, the distance between each of the plates and a corresponding one of the blocks coupled thereto is decreased, and when screw engagement therebetween is released, the distance between each of the plates and a corresponding one of the blocks coupled thereto is increased. Consequently, the height of the space portion 500 is further adjusted through coupling and separation between the plate and the block using the variable fastening member 900.

That is, the height of the space portion 500 may be basically adjusted by block removal, and additionally the height of the space portion 500 may be finely adjusted using the variable fastening member 900.

Hereinafter, various embodiments the present invention will be described with reference to the accompanying drawings. In the drawings showing the embodiments of the present invention, the height of each block, the protrusion length of the lower tip 320 of the probe 300, etc. are somewhat exaggerated for convenience of description. Actually, the height or shape of each block is set in consideration of the degree of wear of the probe 300, and a change in height of the blocks due to at least block removal or block direction change is set so as to be similar to the degree of wear of the probe 300.

### First Embodiment

FIG. 1 shows a first embodiment of the present invention, wherein an upper plate 100, a lower plate 200, a spacer 400 formed between the upper plate 100 and the lower plate 200, and a probe 300 coupled to the upper plate 100 and the lower plate 200 are schematically shown.

The spacer 400 is constituted by three blocks stacked in the upward-downward direction, whereby a space portion 500 has a height L1. That is, the spacer 400 is constituted by three blocks, i.e. an upper block 410, a middle block 420, and a lower block 430, whereby the space portion 500 has a height L1, and a lower tip 320 of the probe 300 under the lower plate has a protrusion length D.

In the first embodiment of the present invention, the upper block 410, the middle block 420, and the lower block 430 constituting the spacer 400 are identical in shape. When the length of the probe 300 is decreased, one of the blocks is removed to adjust the protrusion length of the probe 300.

That is, when the probe 300 is worn during testing, whereby the protrusion length of the lower tip 320 of the probe 300 under the lower plate is decreased, scrubbing between the lower tip and a contact terminal of an object to be tested is not sufficiently performed or appropriate contact pressure against a printed circuit board and the contact terminal of the object to be tested is not maintained. In this case, one of the blocks constituting the spacer 400 is removed to reduce the height of the space portion 500 (L1−>L2, L1>L2), whereby the protrusion length of the lower tip 320 of the probe 300 is readjusted to D.

### Second Embodiment

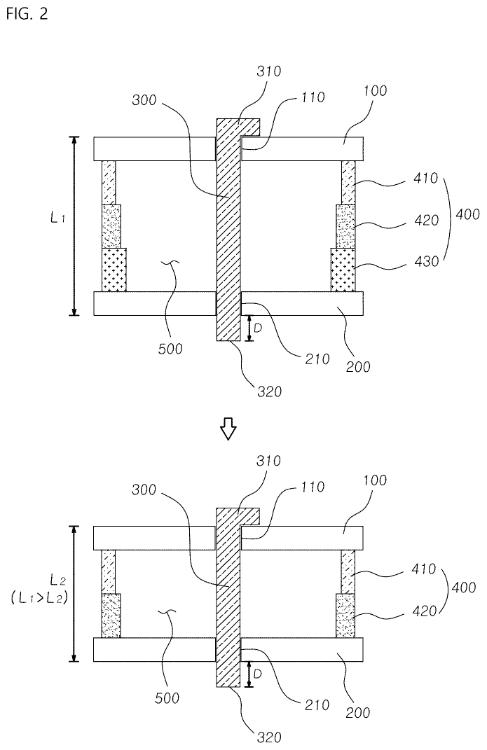

FIG. 2 shows a second embodiment of the present invention, wherein an upper plate 100, a lower plate 200, a spacer 400 formed between the upper plate 100 and the lower plate 200, and a probe 300 coupled to the upper plate 100 and the lower plate 200 are schematically shown.

The second embodiment of the present invention is identical to the first embodiment of the present invention except that the blocks have different shapes. That is, the widths of the blocks are sequentially changed in the upward-downward direction, whereby it is possible to easily recognize at least one block to be removed.

### Third Embodiment

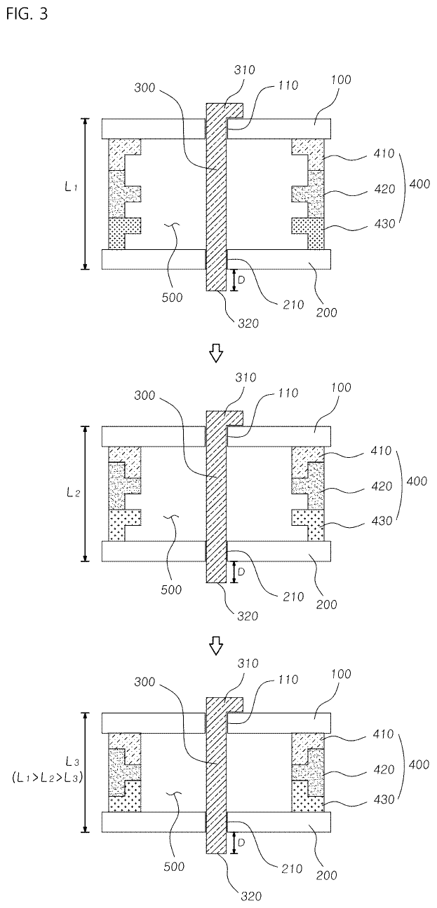

FIG. 3 shows a third embodiment of the present invention, wherein an upper plate 100, a lower plate 200, a spacer 400 formed between the upper plate 100 and the lower plate 200, and a probe 300 coupled to the upper plate 100 and the lower plate 200 are schematically shown.

The third embodiment of the present invention is identical to the first embodiment of the present invention except that the direction in which at least one of the blocks and a corresponding one of the other blocks are coupled to each other is changed and adjacent blocks are recoupled to each other to adjust the height of a space portion 500.

In the third embodiment of the present invention, the direction of an upper block 410 is changed and the upper block 410 is recoupled to a middle block 420, whereby the height of the space portion 500 is reduced from L1 to L2, and the direction of a lower block 430 is changed and the lower block 430 is recoupled to the middle block 420, whereby the height of the space portion 500 is reduced from L2 to L3. As a result, the protrusion length of the probe 300 is adjusted to D.

### Fourth Embodiment

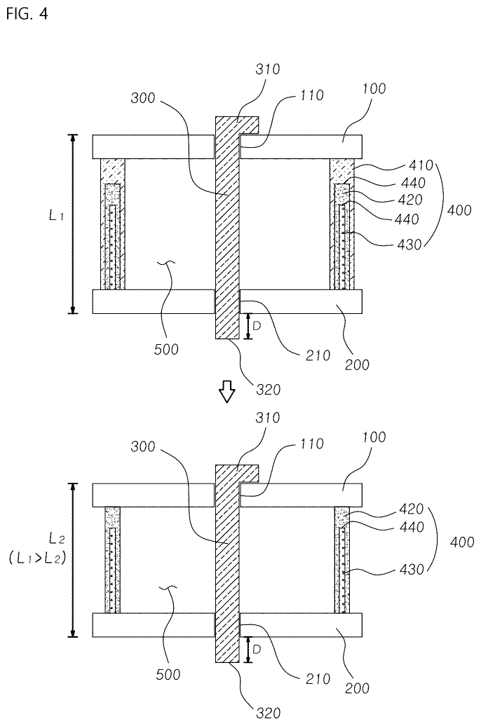

FIG. 4 shows a fourth embodiment of the present invention, wherein an upper plate 100, a lower plate 200, a spacer 400 formed between the upper plate 100 and the lower plate 200, and a probe 300 coupled to the upper plate 100 and the lower plate 200 are schematically shown.

In the fourth embodiment of the present invention, the spacer 400 is constituted by a plurality of blocks stacked in the upward-downward direction, wherein a middle block 420 is inserted into an insertion recess 440 of an upper block 410, and a lower block 430 is inserted into an insertion recess 440 of the middle block 420. The height of each block inserted into the insertion recess 440 is equal to or less than the depth of the insertion recess 440.

When the length of the probe 300 is decreased, the upper block 410 is removed. As a result, the height of a space portion 500 is set (L1−>L2) by the middle block 420 that was inserted into the insertion recess 440 of the upper block 410, and the protrusion length of a lower tip 320 of the probe 300 is adjusted by the difference in height between the upper block 410 and the middle block 420.

### Fifth Embodiment

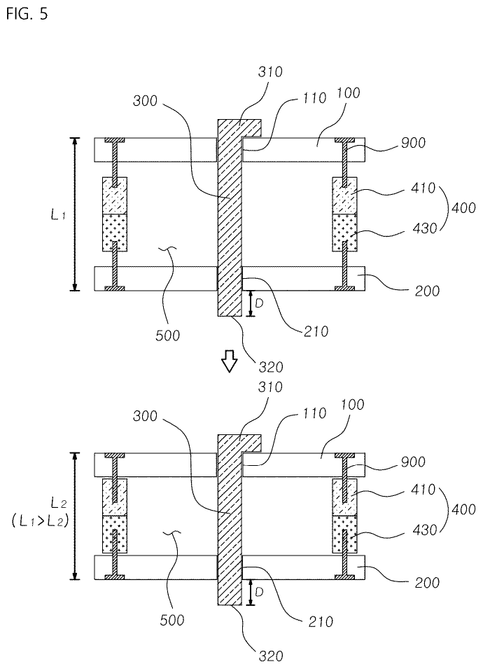

FIG. 5 shows a fifth embodiment of the present invention, wherein an upper plate 100, a lower plate 200, a spacer 400 formed between the upper plate 100 and the lower plate 200, and a probe 300 coupled to the upper plate 100 and the lower plate 200 are schematically shown.

As shown in FIG. 5, the upper plate 100 and an upper block are coupled to each other via a variable fastening member 900, and the lower plate 200 and a lower block are coupled to each other via another variable fastening member 900.

The variable fastening member 900 is constituted by a screw thread having a predetermined length and a screw head. The variable fastening member 900 is configured such that, when the upper plate 100 and the upper block are coupled to each other by screw engagement and when the lower plate 200 and the lower block are coupled to each other by screw engagement, the distance between each of the plates and a corresponding one of the blocks coupled thereto is decreased, and when screw engagement therebetween is released, the distance between each of the plates and a coupled thereto is corresponding one of the blocks increased. Consequently, the height of the space portion 500 is further adjusted (L1−>L2) through coupling and separation between the plate and the block using the variable fastening member 900.

That is, the height of the space portion 500 may be basically adjusted by block removal, and additionally the height of the space portion 500 may be finely adjusted using the variable fastening member 900, whereby the protrusion length of the probe 300 is finely adjusted.

### Sixth Embodiment

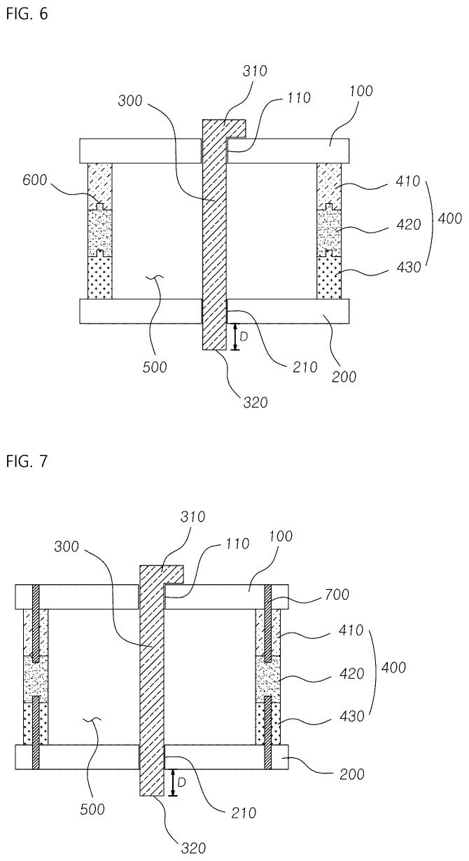

FIGS. 6 to 8 show a coupling means configured to couple the blocks constituting the spacer 400 according to the present invention to each other and a coupling means configured to stably couple the upper plate 100 and the upper block 410 to each other and to stably couple the lower plate 100 and the lower block 410 to each other.

The coupling means may be basically applied to the first to fifth embodiments.

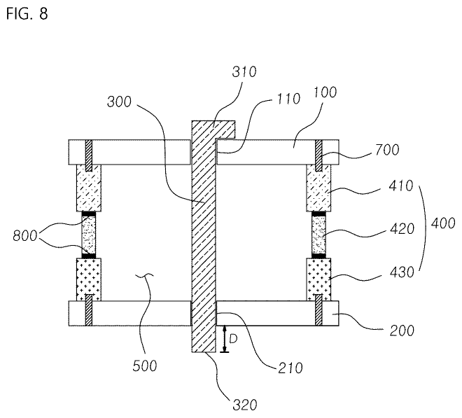

FIG. 6 shows the state in which the blocks are coupled to each other through a concave-convex structure 600, FIG. 7 shows the state in which the blocks are coupled to each other through a screw engagement structure 700, and FIG. 8 shows the state in which the blocks are coupled to each other through an adhesion structure 800 and each of blocks and a corresponding one of the plates are coupled to each other via the screw engagement structure 700.

As described above, the present invention relates to a probe head for testing semiconductor elements, and more particularly to a probe head configured such that the height of a spacer constituted by a plurality of blocks is adjusted, whereby the protrusion length of a probe is adjusted.

The protrusion length of the probe under a lower plate is adjusted, whereby the number of tests is increased, and therefore the lifespan of the probe head is extended. In addition, work time for replacement and reinstallation of the probe head is shortened, whereby delay of a test process is prevented and process cost is reduced.

Furthermore, the protrusion length of the probe is adjustable depending on the degree of wear of the probe, whereby contact between a printed circuit board and a contact terminal of an object to be tested at an appropriate pressure is achieved, and therefore more precise and accurate tests are possible while the printed circuit board and the contact terminal of the object to be tested are protected.

What is claimed is:

1. A probe head for testing semiconductor elements, the probe head comprising:
an upper plate having a first receiving hole formed therein;
a lower plate formed spaced apart from the upper plate, the lower plate having a second receiving hole formed therein;
a probe coupled to the upper plate and the lower plate such that an upper part of the probe is received in the first receiving hole, whereby an upper tip protrudes upwards from the upper plate, and a lower part of the probe is received in the second receiving hole, whereby a lower tip protrudes downwards from the lower plate; and
a spacer formed between the upper plate and the lower plate to separate the upper plate and the lower plate from each other, thereby providing a space portion capable of receiving a middle part of the probe, wherein
the spacer is constituted by a plurality of blocks stacked in an upward-downward direction, and the blocks are configured to be selectively removable to adjust a height of the space portion, whereby a protrusion length of the lower tip of the probe under the lower plate is adjustable.

2. The probe head according to claim 1, wherein the spacer comprises:
an upper block;
a lower block; and
n middle blocks (n being a natural number including 0) provided between the upper block and the lower block.

3. The probe head according to claim 2, wherein
the upper block, the lower block, and the middle blocks are identical in size or shape to each other,
the upper block, the lower block, and the middle blocks are different in size or shape from each other, or
at least one of the upper block, the lower block, and the middle blocks is different in size or shape from the other blocks.

4. The probe head according to claim 2, wherein
the upper block, the lower block, and the middle blocks are formed so as to have sequentially changed widths or heights in the upward-downward direction, or
the upper block, the lower block, and the middle blocks have different colors.

5. The probe head according to claim 2, wherein an indicator for position discrimination is provided at a surface of each of the upper block, the lower block, and the middle blocks.

6. The probe head according to claim 2, wherein any one of a concave-convex structure, a screw engagement structure, and an adhesion structure is formed at coupling surfaces of each of the upper block and the lower block and a corresponding one of the upper plate and the lower plate that face each other such that the coupling surfaces are coupled to each other.

7. The probe head according to claim 2, wherein a concave-convex structure is formed at coupling surfaces of the upper block, the lower block, and the middle blocks that face each other such that the coupling surfaces are coupled to each other by concave-convex coupling.

8. The probe head according to claim 2, wherein a screw engagement structure is formed at coupling surfaces of the upper block, the lower block, and the middle blocks that face each other such that the coupling surfaces are coupled to each other by screw engagement.

9. The probe head according to claim 2, wherein an adhesion structure is formed at coupling surfaces of the upper block, the lower block, and the middle blocks that face each other such that the coupling surfaces are coupled to each other by adhesion.

10. The probe head according to claim 2, wherein two or more of a concave-convex structure, a screw engagement structure, and an adhesion structure are mixedly formed at coupling surfaces of the upper block, the lower block, and the middle blocks that face each other such that the coupling surfaces are coupled to each other.

11. The probe head according to claim 2, wherein at least one of the upper block, the lower block, and the middle blocks is made of an elastic material.

12. The probe head according to claim 2, wherein
the plurality of blocks is stacked such that an insertion recess is formed in a lower part of an uppermost block and a block located under the uppermost block is inserted into the insertion recess, and
a height of the block inserted into the insertion recess is equal to or less than a depth of the insertion recess.

13. The probe head according to claim 1, wherein a direction in which any one of the plurality of blocks is coupled to the other blocks is changed to adjust the height of the space portion.

14. The probe head according to claim 13, wherein a concave-convex structure or a screw engagement structure is formed at a coupling surface of the block having the changed coupling direction that is to face a coupling surface of a corresponding one of the other blocks.

15. The probe head according to claim 2, wherein the upper plate and the upper block or the lower plate and the lower block are coupled to each other via a variable fastening member.

16. The probe head according to claim 1, wherein
the spacer is formed so as to have a quadrangular frame shape such that the space portion is formed in a closed state, or
the spacer is formed so as to have a plurality of bridges located at symmetrical points such that the space portion is formed in an open state.
